(19) United States
(12) Patent Application Publication
(10) Pub. No.: US 2009/0184732 A1
(43) Pub. Date: Jul. 23, 2009

(54) DIFFERENTIAL DRIVING CIRCUIT CAPABLE OF OPERATING AT LOW SUPPLY VOLTAGE WITHOUT REQUIRING COMMON MODE REFERENCE VOLTAGE

(76) Inventors: Kuan-Hua Chao, Taipei County (TW); Tse-Hsiang Hsu, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 12/018,205

(22) Filed: Jan. 23, 2008

(51) Int. Cl. H03K 19/0185

(52) U.S. Cl. 326/83

(57) ABSTRACT

A driving circuit includes a pair of input ports, a pair of differential output ports, a first differential pair, a second differential pair, a load unit, and a current source. The first differential pair is directly connected to a first voltage level, and is coupled to the pair of input ports and the pair of differential output ports. The second differential pair is coupled to the pair of input ports and the pair of differential output ports. The load unit is coupled to the pair of differential output ports. The current source is coupled between the second differential pair and a second voltage level.

### BACKGROUND

The present invention relates to a driving circuit, and more particularly, to a differential driving circuit capable of operating at a low supply voltage without requiring a common mode reference voltage.

In general, a related art differential driving circuit comprises a plurality of differential pairs and a plurality of current sources. The differential driving circuit operates stably at a high supply voltage; however, the differential driving circuit may not operate at a low supply voltage since insufficient head room for multiple current sources (e.g. two current sources, one PMOS, one NMOS) due to lower power supply.

Additionally, it is necessary for the differential driving circuit to utilize a common mode reference voltage to avoid DC voltage levels of differential output signals generated by the driving circuit being shifted due to noise or other factors. Extra cost is incurred, however, by introducing a common mode feedback circuit for generating the desired common mode reference voltage.

Another related art differential driving circuit comprises a differential pair and one current source, and is suitable for operating at a low supply voltage. A disadvantage, however, of this differential driving circuit is that the current source may provide a current twice that provided by the multiple current sources in the above-mentioned differential driving circuit to achieve the goal of providing an identical output voltage swing. Power consumption caused by this current source providing more current amounts in the conventional design may be more than that caused by the multiple current sources in the above-mentioned differential driving circuit. It is therefore important to provide a differential driving circuit capable of operating at a low supply voltage and providing an identical output voltage swing without extra power consumption.

### SUMMARY

A differential driving circuit capable of operating at a low supply voltage without a common mode reference voltage and providing an identical output voltage swing without additional power consumption to solve the above-mentioned problems is therefore provided.

According to one embodiment, a driving circuit is disclosed. A driving circuit comprises a pair of input ports, a pair of differential output ports, a first differential pair, a second differential pair, a load unit and a current source. The first differential pair is directly connected to a first voltage level, and has a first input terminal coupled to one of the input ports, a second input terminal coupled to the other of the input ports, a first output terminal coupled to one of the differential output ports, and a second output terminal coupled to the other of the differential output ports. The second differential pair has a first input terminal coupled to one of the input ports, a second input terminal coupled to the other of the input ports, a first output terminal coupled to one of the differential output ports, and a second output terminal coupled to the other of the differential output ports. The load unit is coupled to the pair of differential output ports. The current source is coupled between the second differential pair and a second voltage level.

According to another embodiment, a driving circuit is disclosed. A driving circuit comprises a pair of input ports, a pair of differential output ports, a first transistor, a second transistor, a third transistor, a fourth transistor, a load unit and a current source. The first transistor has a source terminal directly connected to a first voltage level, a drain terminal coupled to one of the differential output ports, and a gate terminal coupled to one of the input ports. The second transistor has a source terminal directly connected to the first voltage level, a drain terminal coupled to the other of the differential output ports, and a gate terminal coupled to the other of the input ports. The third transistor has a drain terminal coupled to one of the differential output ports, and a gate terminal coupled to one of the input ports. The fourth transistor has a drain terminal coupled to the other of the differential output ports, and a gate terminal coupled to the other of the input ports. The load unit is coupled to the pair of differential output ports. The current source is coupled between a second voltage level and the sources of the third and fourth transistors.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a driving circuit according to a first embodiment of the present invention.

FIG. 2 is a diagram of a driving circuit according to a second embodiment of the present invention.

### DETAILED DESCRIPTION

Certain terms are used throughout the description and following claims to refer to particular components. As one skilled in the art will appreciate, electronic equipment manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

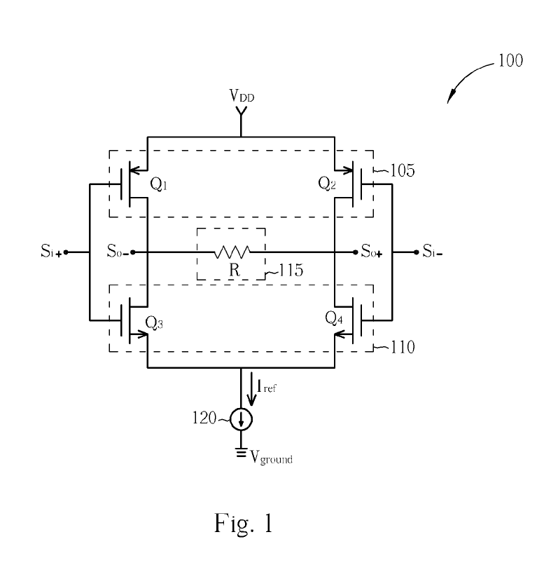

Please refer to FIG. 1. FIG. 1 is a diagram of a driving circuit 100 according to a first embodiment of the present invention. The driving circuit 100 comprises two differential pairs 105 and 110, a load unit 115, and a current source 120. The differential pair 105 is directly connected to a first voltage level (e.g. a supply voltage V_{DD}), and coupled to differential output ports and input ports of the driving circuit 100. The differential pair 105 comprises transistors Q₁, Q₂, and one of the transistors Q₁, Q₂ is selectively turned on according to input signals S_{i +}, S_{i -} received from the input ports of the driving circuit 100. The differential pair 110 comprises transistors Q₃, Q₄, and one of the transistors Q₃, Q₄ is selectively turned on according to input signals Sᵢ₊, Sᵢ₋ received from the input ports of the driving circuit 100. In this embodiment, the load unit 115 is implemented with a resistance element, e.g. a resistor, coupled to the differential output ports of the driving circuit 100, where the resistance of the resistor equals R. The current source 120 is coupled to the differential pair 110 and a second voltage level (e.g. a ground level V_{ground}).

More particularly, the transistors Q₁, Q₂ are PMOS transistors, and the transistors Q₃, Q₄ are NMOS transistors. The transistor Q₁ has a source terminal directly connected to the supply voltage V_{DD}, a drain terminal coupled to a differential output port Sₒ₋, and a gate terminal coupled to the input port Sᵢ₊. The transistor Q₂ has a source terminal directly connected to the supply voltage V_{DD}, a drain terminal coupled to a differential output port Sₒ₊, and a gate terminal coupled to the input ports Sᵢ₋. The transistor Q₃ has a drain terminal coupled to the differential output port Sₒ₋, a source terminal coupled to the current source 120, and a gate terminal coupled to the input port Sᵢ₊. The transistor Q₄ has a drain terminal coupled to the differential output port Sₒ₊, a source terminal coupled to the current source 120, and a gate terminal coupled to the input port Sᵢ₋. The operation of the driving circuit 100 is detailed as follows.

The input signals Sᵢ₊ and Sᵢ₋ typically have different logic levels, and therefore one of the transistors in each differential pair 105, 110 will be turned on while the other of the transistors in each differential pair 105, 110 will be turned off. The current source 120 is utilized for providing a reference current I_{ref} passing through the above-mentioned conducting transistors.

For example, when the transistor Q₁ is turned on by the input signal Sᵢ₊ and the transistor Q₄ is turned on by the input signal Sᵢ₋, the reference current I_{ref} provided by the current source 120 passes through the transistor Q₁, the load unit 115, and the transistor Q₄. The voltage level of the differential output signal Sₒ₋ at the differential output port of the driving circuit 100 approximates to the voltage level V_{DD} since the voltage drop across the transistor Q₁ is very low and therefore can be omitted. The voltage level of the differential output signal Sₒ₊ at the differential output port of the driving circuit 100 approximates to a value of V_{DD}-I_{ref}R. Similarly, when the transistor Q₃ is turned on by the input signal Sᵢ₊ and the transistor Q₂ is turned on by the input signal Sᵢ₋, the reference current I_{ref} provided by the current source 120 passes through the transistor Q₂, the load unit 115, and the transistor Q₃. The voltage level of the differential output signal Sₒ₊ approximates to the voltage level V_{DD} since the voltage drop across the transistor Q₂ is very low and therefore can be omitted. The voltage level of the differential output signal Sₒ₋ approximates to a value of V_{DD}-I_{ref}xR.

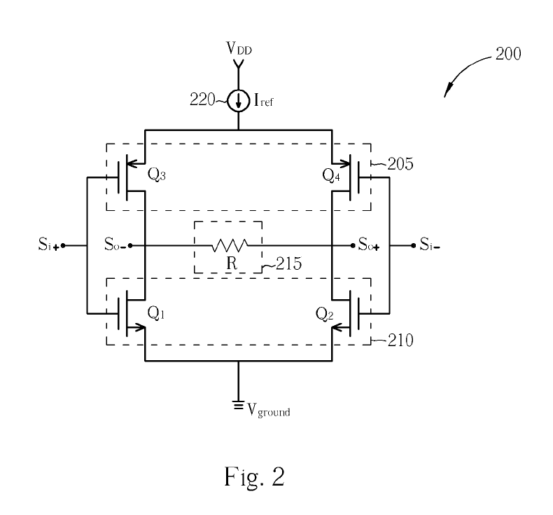

Please refer to FIG. 2. FIG. 2 is a diagram of a driving circuit 200 according to a second embodiment of the present invention. The driving circuit 200 comprises two differential pairs 205 and 210, a load unit 215, and a current source 220. The differential pair 205 comprises a plurality of transistors Q₃, Q₄, and the differential pair 210 comprises a plurality of transistors Q₁, Q₂. In this embodiment, the load unit 215 is implemented with a resistance element, e.g. a resistor, coupled to the differential output ports of the driving circuit 200, where the resistance of the resistor equals R.

The operation and function of the differential pairs 205, 210, the load unit 215, and the current source 220 are similar to that of the differential pairs 105, 110, the load unit 115, and the current source 120 mentioned above; further description is omitted for brevity. However, the driving circuit 100 and the driving circuit 200 have some differences. For example, the current source 120 is directly connected to the differential pair 110 and coupled to a first voltage (e.g. a ground level V_{ground}). The current source 220 is coupled between a second voltage level (e.g. the supply level V_{DD}) and the differential pair 205. Therefore, when the transistor Q₃ is turned on by the input signal Sᵢ₊ and the transistor Q₂ is turned on by the input signal Sᵢ₋, a reference current I_{ref} provided by the current source 220 passes through the transistor Q₃, the load unit 215, and the transistor Q₂. The voltage level of a differential output signal Sₒ₊ at a differential output port of the driving circuit 200 approximates to the ground level V_{ground} (e.g. the voltage level of the differential output signal Sₒ₊ approximates to zero) since the voltage drop across the transistor Q₂ is very low and therefore can be omitted. The voltage level of a differential output signal Sₒ₋ at another differential output port of the driving circuit 200 approximates to a value of I_{ref}xR. Similarly, when the transistor Q₁ is turned on by the input signal Sᵢ₊ and the transistor Q₄ is turned on by the input signal Sᵢ₋, the reference current I_{ref} provided by the current source 220 passes through the transistor Q₄, the load unit 215, and the transistor Q₁. The voltage level of the differential output signal Sₒ₋ approximates to zero since the voltage drop across the transistor Q₁ is very low and therefore can be omitted. The voltage level of the differential output signal Sₒ₊ approximates to a value of I_{ref}xR. After reading the above disclosure, a person skilled in this art can readily appreciate that other circuit configurations are possible.

As mentioned above, by directly connecting a differential pair in a driving circuit to a voltage level (e.g. directly connecting the differential pair 105 to the supply voltage V_{DD} in the first embodiment or directly connecting the differential pair 210 to the ground level V_{ground} in the second embodiment), the driving circuit only utilizes one current source to achieve the goal of operating the driving circuit at a low supply voltage environment. By the circuit of the embodiment, the current flows through all resistance rather than half of them, so as to decrease the power consumption. Additionally, since a voltage drop across a conducting transistor in the differential pair directly connected to the voltage level (e.g. the voltage drops across the transistors Q₁, Q₂ in the first embodiment in the second embodiment) is very small and therefore can be omitted, a common mode reference voltage is not required for the disclosed driving circuit.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A driving circuit, comprising:
a pair of input ports;
a pair of differential output ports;
a first differential pair, directly connected to a first voltage level, having a first input terminal coupled to one of the input ports, a second input terminal coupled to the other of the input ports, a first output terminal coupled to one of the differential output ports, and a second output terminal coupled to the other of the differential output ports;
a second differential pair, having a first input terminal coupled to one of the input ports, a second input terminal coupled to the other of the input ports, a first output terminal coupled to one of the differential output ports, and a second output terminal coupled to the other of the differential output ports;
a load unit, coupled to the pair of differential output ports; and
a current source, coupled between the second differential pair and a second voltage level.

2. The driving circuit of claim 1, wherein the first differential pair comprises:
a first transistor having a source terminal directly connected to the first voltage level, a drain terminal coupled to one of the differential output ports, and a gate terminal coupled to one of the input ports; and
a second transistor having a source terminal directly connected to the first voltage level, a drain terminal coupled to the other of the differential output ports, and a gate terminal coupled to the other of the input ports.

3. The driving circuit of claim 2, wherein the second differential pair comprises:
a third transistor having a drain terminal coupled to one of the differential output ports, and a gate terminal coupled to one of the input ports; and
a fourth transistor having a drain terminal coupled to the other of the differential output ports, and a gate terminal coupled to the other of the input ports.

4. The driving circuit of claim 3, wherein the first voltage level is higher than the second voltage level.

5. The driving circuit of claim 4, wherein the first transistor and the second transistor are PMOS transistors, and the third transistor and the fourth transistor are NMOS transistors.

6. The driving circuit of claim 3, wherein the second voltage level is higher than the first voltage level.

7. The driving circuit of claim 6, wherein the first transistor and the second transistor are NMOS transistors, and the third transistor and the fourth transistor are PMOS transistors.

8. The driving circuit of claim 1, wherein the load unit is a resistance element.

9. A driving circuit, comprising:
a pair of input ports;
a pair of differential output ports;
a first transistor having a source terminal directly connected to a first voltage level, a drain terminal coupled to one of the differential output ports, and a gate terminal coupled to one of the input ports;
a second transistor having a source terminal directly connected to the first voltage level, a drain terminal coupled to the other of the differential output ports, and a gate terminal coupled to the other of the input ports;
a third transistor having a drain terminal coupled to one of the differential output ports, and a gate terminal coupled to one of the input ports;
a fourth transistor having a drain terminal coupled to the other of the differential output ports, and a gate terminal coupled to the other of the input ports;
a load unit, coupled to the pair of differential output ports; and
a current source, coupled between a second voltage level and the sources of the third and fourth transistors.

10. The driving circuit of claim 9, wherein the first voltage level is higher than the second voltage level.

11. The driving circuit of claim 10, wherein the first transistor and the second transistor are PMOS transistors, and the third transistor and the fourth transistor are NMOS transistors.

12. The driving circuit of claim 9, wherein the second voltage level is higher than the first voltage level.

13. The driving circuit of claim 12, wherein the first transistor and the second transistor are NMOS transistors, and the third transistor and the fourth transistor are PMOS transistors.

14. The driving circuit of claim 9, wherein the load unit is a resistance element.
